(19) United States
(12) Patent Application Publication
(10) Pub. No.: US 2025/0275400 A1
(43) Pub. Date: Aug. 28, 2025

(54) LIGHT EMITTING DEVICE, WEARABLE DEVICE, DISPLAY DEVICE, PHOTOELECTRIC CONVERSION DEVICE, ELECTRONIC APPARATUS, ILLUMINATION DEVICE, AND MOVING BODY

(71) Applicant: CANON KABUSHIKI KAISHA, Tokyo (JP)

(72) Inventors: MARI ISOBE, Kanagawa (JP); YASUSHI MATSUNO, Kanagawa (JP); TETSURO YAMAMOTO, Kanagawa (JP)

(21) Appl. No.: 19/051,535

(22) Filed: Feb. 12, 2025

(30) Foreign Application Priority Data
Feb. 22, 2024 (JP) 2024-025574

(51) Int. Cl. H10K 59/131; B60Q 1/44; F21S 43/145; F21V 3/00; F21Y 115/15; G09G 3/00; G09G 3/3233; H04N 23/53; H10K 59/95

(52) U.S. Cl. CPC H10K 59/131; F21S 43/145; F21V 3/00; G09G 3/001; G09G 3/3233; H04N 23/53; H10K 59/95; B60Q 1/44; F21Y 2115/15; G09G 2300/0842; G09G 2320/0233; G09G 2340/0407

(57) ABSTRACT

Alight emitting device including, on a main surface of a semiconductor substrate, a display region in which pixels are arranged, is provided. The main surface includes a first region in which a first conductive pattern is arranged, and a second region which is adjacent to the first region and in which a second conductive pattern is arranged. Each of the pixels includes an organic light emitting element and a driving transistor. Each of the first conductive pattern and the second conductive pattern includes a conductive pattern connected to a gate electrode of the driving transistor in one of the pixels. The first region and the second region are adjacent at a boundary with a deviation between the first conductive pattern and the second conductive pattern, and the boundary does not pass through a center of the display region.

### BACKGROUND OF THE INVENTION

### Field of the Invention

The present disclosure relates to a light emitting device, a wearable device, a display device, a photoelectric conversion device, an electronic apparatus, an illumination device, and a moving body.

### Description of the Related Art

Recently, in a light emitting device using an organic light emitting element such as an organic light emitting diode (OLED), a light emitting device having a higher resolution has been demanded along with the development of the virtual reality (VR) and augmented reality (AR) technologies. To increase the resolution, there is known a micro OLED in which transistors are formed on a silicon wafer using a semiconductor fine-process technology. In addition, a light emitting device including more pixels is required, and as a result, a light emitting device having a larger size is demanded. However, a size that an exposure apparatus used in the semiconductor fine-process technology can expose is generally about 33 mm×26 mm. When manufacturing a light emitting device having a large size, it is considered that a region to expose is divided into two or more regions, and stitching exposure is performed. Japanese Patent Laid-Open No. 2021-064001 shows flexibly setting the position of a stitching portion between adjacent patterns in a semiconductor device.

### SUMMARY OF THE INVENTION

Japanese Patent Laid-Open No. 2021-064001 shows setting the stitching portion to a visually unnoticeable position in an image capturing device or the like. However, an influence on image quality derived from the stitching exposure in a light emitting device using an organic light emitting element is not disclosed in Japanese Patent Laid-Open No. 2021-064001.

Some embodiments of the present disclosure provide a technique advantageous in suppressing image quality degradation caused by stitching exposure in a light emitting device using an organic light emitting element.

According to some embodiments, a light emitting device comprising, on a main surface of a semiconductor substrate, a display region in which a plurality of pixels are arranged, wherein the main surface includes a first region in which a first conductive pattern is arranged, and a second region which is adjacent to the first region and in which a second conductive pattern is arranged, each of the plurality of pixels includes an organic light emitting element, and a driving transistor configured to supply a current according to a luminance signal to the organic light emitting element, each of the first conductive pattern and the second conductive pattern includes a conductive pattern connected to a gate electrode of the driving transistor in one of the plurality of pixels, the first region and the second region are adjacent at a boundary with a deviation between the first conductive pattern and the second conductive pattern, and the boundary does not pass through a center of the display region, is provided.

Further features of the present invention will become apparent from the following description of exemplary embodiments with reference to the attached drawings.

### BRIEF DESCRIPTION OF THE DRAWINGS

FIG. 1 is a sectional view showing an example of the configuration of a light emitting device according to the embodiment.

FIG. 2 is a circuit diagram showing an example of the configuration of a pixel of the light emitting device shown in FIG. 1.

FIG. 3 is a plan view showing an example of the arrangement of the pixels shown in FIG. 2.

FIG. 4 is a plan view showing an example of the configuration of the light emitting device shown in FIG. 1.

FIG. 5 is a plan view showing an example of the configuration of the light emitting device shown in FIG. 1.

FIG. 6 is a plan view showing an example of the configuration of the light emitting device shown in FIG. 1.

FIG. 7 is a plan view showing an example of the configuration of the light emitting device shown in FIG. 1.

FIGS. 8A and 8B are views showing an example of the configuration of a head mounted display using the light emitting device shown in FIG. 1.

FIGS. 9A and 9B are sectional views showing an example of the configuration of the pixel of the light emitting device shown in FIG. 1.

FIG. 10 is a view showing an example of a display device using the light emitting device according to the embodiment.

FIG. 11 is a view showing an example of a photoelectric conversion device using the light emitting device according to the embodiment.

FIG. 12 is a view showing an example of an electronic apparatus using the light emitting device according to the embodiment.

FIGS. 13A and 13B are views showing an example of a display device using the light emitting device according to the embodiment.

FIG. 14 is a view showing an example of an illumination device using the light emitting device according to the embodiment.

FIG. 15 is a view showing an example of a moving body using the light emitting device according to the embodiment.

FIGS. 16A and 16B are views showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

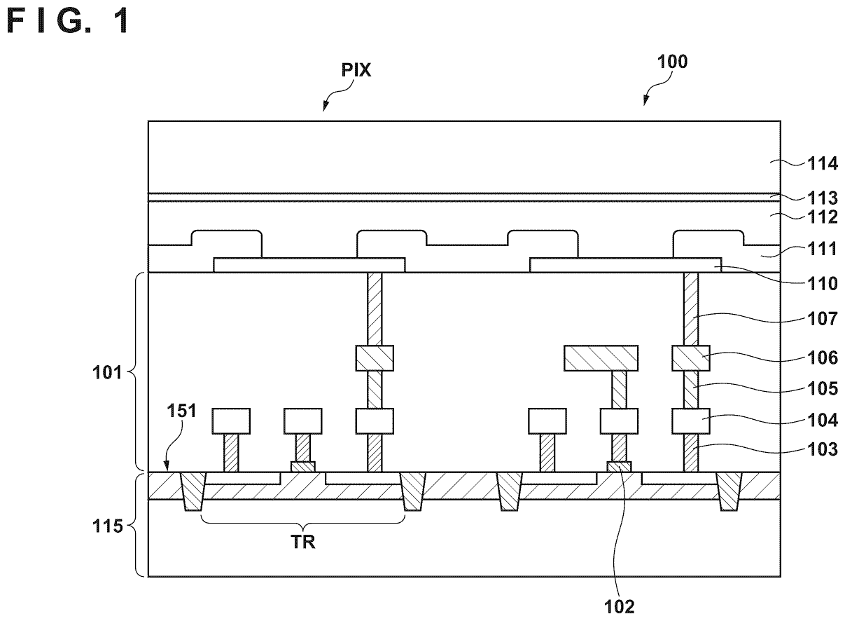

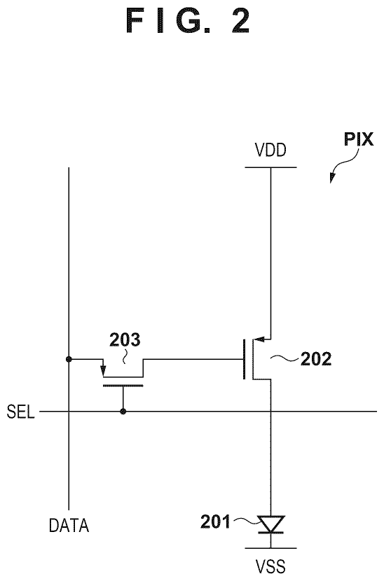

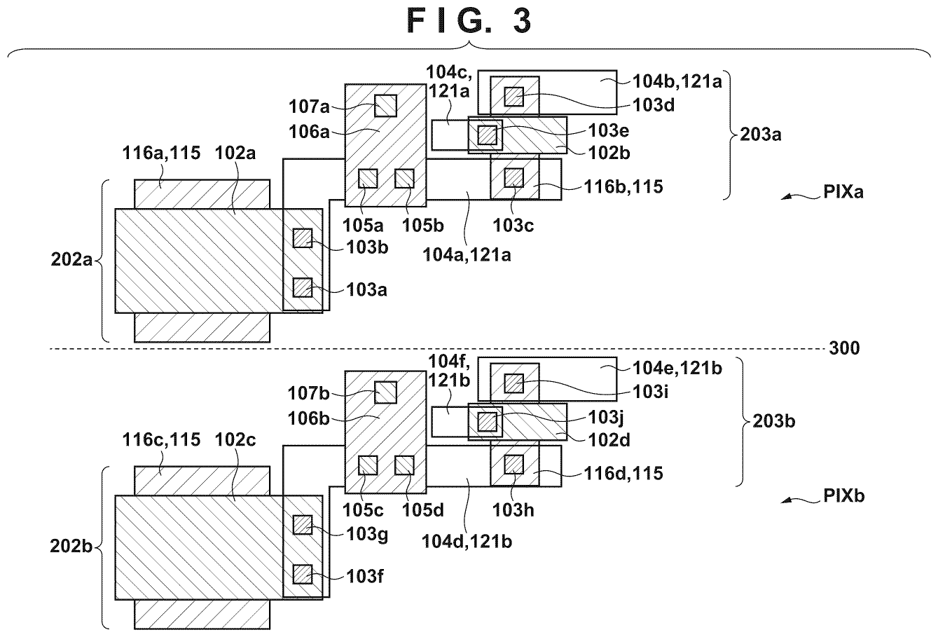

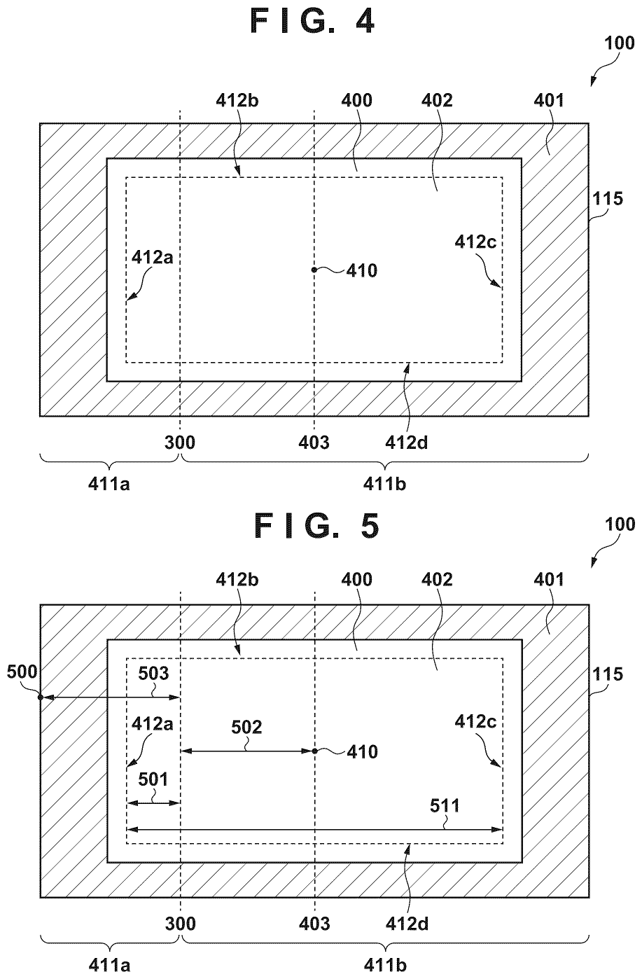

Alight emitting device according to an embodiment of the present disclosure will be described with reference to FIGS. 1 to 8A and 8B. FIG. 1 is a sectional view showing an example of the configuration of a light emitting device 100 according to this embodiment. FIG. 2 is a view showing an example of the configuration of a driving circuit of a pixel PIX arranged in the light emitting device 100. FIG. 3 is a plan view showing an example of the arrangement of the driving circuit shown in FIG. 2. FIG. 4 is a plan view showing an example of the configuration of the light emitting device 100.

The light emitting device 100 includes, on a main surface 151 of a substrate 115, a display region 402 (also called an effective pixel region) in which a plurality of pixels PIX are arranged. For the substrate 115, a semiconductor such as silicon can be used. A wiring structure 101 is arranged on the substrate 115 provided with a transistor TR. The wiring structure 101 includes an insulator using silicon oxide or the like, wiring patterns arranged in the insulator, plugs for connecting the wiring patterns to each other, and the like. A lower electrode 110 that forms an organic light emitting element, an insulating layer 111, an organic layer 112 including a light emitting layer, and an upper electrode 113 are arranged on the wiring structure 101. A protection layer 114 can be arranged on the organic light emitting element.

The transistor TR includes, for example, a gate electrode 102. FIG. 1 shows the wiring structure 101 having a two-layered structure including a wiring layer in which a wiring pattern 104 is arranged, and a wiring layer in which a wiring pattern 106 is arranged. Plugs 103 connected to the gate electrode 102 or the substrate 115 are arranged in the wiring structure 101. The plugs 103 connect the gate electrode 102 and the wiring pattern 104, and the substrate 115 and the wiring pattern 104. Also, a plug 105 that connects the wiring pattern 104 and the wiring pattern 106 and a plug 107 that connects the wiring pattern 106 and the lower electrode 110 are arranged in the wiring structure 101. In the configuration shown in FIG. 1, there exist two wiring layers each having a wiring pattern arranged therein. However, there may be one wiring layer or three or more wiring layers in accordance with the configuration of the light emitting device 100.

FIG. 2 shows an example of the configuration of the circuit of the pixel PIX according to this embodiment. The pixel PIX can include an organic light emitting element 201, a driving transistor 202, and a write transistor 203. The above-described transistor TR corresponds to the driving transistor 202 or the write transistor 203. In the write transistor 203, the gate electrode 102 is connected to a signal line SEL, and one main terminal (a source in the configuration shown in FIG. 2) is connected to a signal line DATA. The gate electrode 102 of the driving transistor 202 is connected to the other main terminal (a drain in the configuration shown in FIG. 2) of the write transistor 203. One main terminal (a source in the configuration shown in FIG. 2) of the driving transistor 202 is connected to a power supply line VDD, and the other main terminal (a drain in the configuration shown in FIG. 2) of the driving transistor 202 is connected to one main terminal of the organic light emitting element 201. The other main terminal of the organic light emitting element 201 is connected to a power supply line VSS. If the write transistor 203 is rendered conductive in accordance with a signal supplied to the signal line SEL, a predetermined potential is supplied as a luminance signal from the signal line DATA to the gate electrode 102 of the driving transistor 202. The driving transistor 202 supplies a current according to the potential of the luminance signal to the organic light emitting element 201. The organic light emitting element 201 thus emits light in a luminance according to the luminance signal (current driving).

FIG. 3 is a plan view showing an example of the arrangement of two pixels PIXa and PIXb according to this embodiment. In the actual pixels PIXa and PIXb, components that are not shown in FIG. 3 exist, and FIG. 3 shows only minimum components necessary for the description. As shown in FIG. 2, the pixels PIXa and PIXb include driving transistors 202a and 202b and write transistors 203a and 203b, respectively. The driving transistors 202a and 202b include source/drain regions 116a and 116c and gate electrodes 102a and 102c provided on the substrate 115, respectively. The write transistors 203a and 203b include source/drain regions 116b and 116d and gate electrodes 102b and 102d provided on the substrate 115, respectively.

The gate electrode 102a of the driving transistor 202a and the drain of the write transistor 203a are connected via plugs 103a and 103b, a wiring pattern 104a, and a plug 103c. The wiring pattern 104a forms a part of the wiring pattern 104 shown in FIG. 1. Also, the wiring pattern 104a may be connected, via plugs 105a and 105b, to a wiring pattern 106a that forms a part of the wiring pattern 106 shown in FIG. 1. As shown in FIG. 3, a plug 107a may be connected to the wiring pattern 106a. The wiring patterns 104a and 106a, and the plugs 103a, 103b, 103c, 105a, 105b, and 107a are patterns connected to the gate electrode 102a of the driving transistor 202a. It can be said that the wiring patterns 104a and 106a, and the plugs 103a, 103b, 103c, 105a, 105b, and 107a are patterns that are equipotential to the gate electrode 102a of the driving transistor 202a if wiring resistances and a transient potential variation are neglected. A wiring pattern 104b forms a part of the wiring pattern 104 shown in FIG. 1. Also, the wiring pattern 104b is a pattern connected to the source of the write transistor 203a via a plug 103d. A wiring pattern 104c forms a part of the wiring pattern 104 shown in FIG. 1. The wiring pattern 104c is a pattern connected to the gate electrode 102b of the write transistor 203a via a plug 103e.

Similarly, the gate electrode 102c of the driving transistor 202b and the drain of the write transistor 203a are connected via plugs 103f and 103g, a wiring pattern 104d, and a plug 103h. The wiring pattern 104d forms a part of the wiring pattern 104 shown in FIG. 1. Also, the wiring pattern 104d may be connected, via plugs 105c and 105d, to a wiring pattern 106b that forms a part of the wiring pattern 106 shown in FIG. 1. As shown in FIG. 3, a plug 107b may be connected to the wiring pattern 106b. The wiring patterns 104d and 106b, and the plugs 103f, 103g, 103h, 105c, 105d, and 107b are patterns connected to the gate electrode 102c of the driving transistor 202b. It can be said that the wiring patterns 104d and 106b, and the plugs 103f, 103g, 103h, 105c, 105d, and 107b are patterns that are equipotential to the gate electrode 102a of the driving transistor 202a if wiring resistances and a transient potential variation are neglected. The wiring pattern 104e forms a part of the wiring pattern 104 shown in FIG. 1. Also, the wiring pattern 104e is a pattern connected to the source of the write transistor 203b via a plug 103i. A wiring pattern 104f forms a part of the wiring pattern 104 shown in FIG. 1. The wiring pattern 104f is a pattern connected to the gate electrode 102d of the write transistor 203b via a plug 103j.

In this embodiment, when manufacturing the light emitting device 100, for some components, the region to expose is divided into two or more regions, and stitching exposure is performed. For example, in an exposure process when forming the wiring pattern 104 shown in FIG. 3, stitching exposure is executed using, as a boundary, a boundary 300 between the pixel PIXa and the pixel PIXb. The wiring pattern 104 is a pattern arranged in the wiring layer closest to the gate electrode 102 in a plurality of wiring layers arranged in the display region 402. On the other hand, the gate electrode 102, the plug 103, the plug 105, the wiring pattern 106, and the plug 107, and the like may be formed by one-shot exposure. However, the pattern formed using stitching exposure is not limited to the wiring pattern 104. For example, the gate electrode 102 may be formed using stitching exposure. Also, for example, the wiring pattern 106 that is a pattern arranged in the second closest wiring layer to the gate electrode 102 in the plurality of wiring layers arranged in the display region 402 may be formed using stitching exposure. Furthermore, for example, one of the plug 103 connected to the gate electrode 102 or the substrate 115, the plug 105 connected to the wiring pattern 104, and the plug 107 connected to the wiring pattern 106 may be formed using stitching exposure.

For example, in a layer where fine pattern formation is needed, stitching exposure by ArF exposure may be used, and in a layer where a relatively large pattern is formed, one-shot exposure by KrF exposure or i-line exposure may be used. Wiring patterns and plugs formed using stitching exposure will sometimes be referred to as conductive patterns 121 hereinafter. In the configuration shown in FIG. 3, the wiring pattern 104 (the wiring patterns 104a to 104f) is the conductive pattern 121 formed using stitching exposure.

If stitching exposure is used, the line width of the wiring pattern 104 that is the conductive pattern 121 formed using stitching exposure may have a different value for each divided and exposed region. In addition, the overlay amount of the wiring pattern 104 to the patterns in another layer (for example, a layer formed using one-shot exposure), for example, the gate electrode 102, the plugs 103 and 105, the wiring pattern 106, and the like may also change. More specifically, the line width may change at the boundary 300 between the wiring pattern 104a included in a conductive pattern 121a and the wiring pattern 104d included in a conductive pattern 121b. Similarly, the line width may change between the wiring pattern 104c (conductive pattern 121a) and the wiring pattern 104f (conductive pattern 121b). Accordingly, the parasitic capacitance between the wiring pattern 104a and the wiring pattern 104c and the parasitic capacitance between the wiring pattern 104d and the wiring pattern 104f may have different values. The wiring patterns 104c and 104f are the signal lines SEL shown in FIG. 2. That is, the parasitic capacitance between the signal line SEL and the gate electrode 102 of the driving transistor 202 can vary at the boundary 300 of stitching exposure.

The parasitic capacitance between the signal line SEL and the gate electrode 102 of the driving transistor 202 affects a voltage applied from the signal line DATA to the gate electrode 102 of the driving transistor 202 when the write transistor 203 is rendered conductive. If the value of the parasitic capacitance is different, the voltage applied to the gate electrode 102 of the driving transistor 202 changes even in a case where the supplied luminance signal is the same, and the amount of the current flowing to the organic light emitting element 201 changes. That is, the amount of the current flowing to the organic light emitting element 201 varies for each exposure region in stitching exposure, and the light emission intensity of the organic light emitting element 201 may change at the boundary 300 of stitching exposure.

As shown in FIG. 4, the display region 402 including the above-described pixels PIX is arranged on the main surface 151 of the substrate 115. A dummy pixel region 400 in which dummy pixels are arranged is arranged around the display region 402. A dummy pixel can be a pixel that has the same configuration as the pixel PIX but does not emit light. For example, in the dummy pixel, the plug 107 that connects the wiring pattern 106 and the lower electrode 110 may not be arranged. A peripheral region 401 is arranged around the dummy pixel region 400. A circuit configured to operate the pixel PIX, and the like can be arranged in the peripheral region 401.

On the main surface 151 of the substrate 115, the conductive pattern 121 (for example, the above-described wiring pattern 104) formed by stitching exposure at the boundary 300, as described above, is arranged. It can be said that the main surface 151 of the substrate 115 includes, on both sides of the boundary 300, a region 411a where the conductive pattern 121a (for example, the wiring patterns 104a to 104c) formed using stitching exposure is arranged and a region 411b where the conductive pattern 121b (for example, the wiring patterns 104d to 104f) is arranged. In this case, as described above, for example, the conductive pattern 121a arranged in the region 411a and the conductive pattern 121b arranged in the region 411b may have different line widths. In addition, the relative position with respect to the layer formed using one-shot exposure may be different between the conductive pattern 121a arranged in the region 411a and the conductive pattern 121b arranged in the region 411b. Hence, the region 411a and the region 411b are adjacent to each other at the boundary with the deviation between the conductive pattern 121a and the conductive pattern 121b.

The display region 402 can have, for example, a substantially rectangular shape having sides 412a to 412d, as shown in FIG. 4. The sides 412a to 412d can be virtual lines that connect the centers of the pixels PIX arranged at the vertices of the display region 402. Here, the center of the pixel PIX can be defined as the position of the geometrical center of gravity in the whole configuration or a specific component of the pixel PIX in the orthogonal projection to the main surface 151 of the substrate 115. For example, the center of the pixel PIX may be the position of the geometrical center of gravity of a region of the pixel PIX, where light is emitted, in the orthogonal projection to the main surface 151 of the substrate 115. The position of the geometrical center of gravity of the rectangle defined by the sides 412a to 412d in the orthogonal projection to the main surface 151 of the substrate 115 is defined as a center 410 of the display region. In this case, the boundary 300 when executing stitching exposure is arranged not to pass through the center of the display region 402.

As described above, in the conductive pattern 121 formed using stitching exposure, a pattern size difference or misalignment occurs between regions 411. This may change the light emission intensity of the organic light emitting element 201 at the boundary 300 of stitching exposure. This can prevent the boundary 300 of stitching exposure from being arranged at the center of the display region 402 which is most likely to stand out to a viewer. As a result, even if the boundary 300 passes through the display region 402, and the light emission intensity changes between the region 411a and the region 411b at the boundary 300, it is possible to suppress visually recognizing the difference of the light emission intensity. As a result, in the light emitting device 100 using the organic light emitting element 201, image quality degradation caused by stitching exposure is suppressed.

For example, as shown in FIG. 4, the boundary 300 may be arranged between the center 410 of the display region 402 and the side 412a that forms the outer edge of the display region 402. In this case, the boundary 300 may extend parallel to the direction in which the side 412a extends. In this case, it can be said that the boundary 300 is arranged between a center line 403 that passes through the center 410 of the display region 402 and is parallel to the direction in which the side 412a extends and the side 412a that forms the outer edge of the display region 402. The configuration shown in FIG. 4 shows an example in which, in the orthogonal projection to the main surface 151 of the substrate 115, the rectangular shape of the outer edge of the display region 402 has long sides and short sides, and the boundary 300 is arranged parallel to the side 412a that forms a short side. However, the present invention is not limited to this, and the boundary 300 may be arranged parallel to the sides 412b and 412d that form the long sides. Also, the outer edge of the display region 402 may have a square shape.

An example in which the boundary 300 of stitching exposure is arranged at a position more difficult for a person to visually recognize will be described next with reference to FIG. 5. The relationship of the components in the orthogonal projection to the main surface 151 of the substrate 115 will be shown below unless it is specifically stated otherwise in this specification.

As described above, the boundary 300 of stitching exposure does not pass through the center of the display region 402. Also, in the configuration shown in FIG. 5, in a direction crossing the direction in which the boundary 300 extends, the boundary 300 is arranged between the side 412a among sides 412 that form the outer edge of the display region 402 and the center 410 of the display region 402. At this time, a length 502 between the boundary 300 and the center 410 of the display region 402 may be equal to or more than a length 501 between the boundary 300 and the side 412a. As shown in FIG. 5, the length between the side 412a and the side 412c, which are parallel to each other and form the outer edge of the display region 402, is defined as a length 511. The length 511 is the length of the display region 402 in the direction crossing the boundary 300. In this case, the boundary 300 is arranged within the range of a distance ¼ the length 511 from the side 412a. Thus, the boundary 300 is apart from the center of the display region 402, and visually recognizing the boundary 300 is suppressed.

Also, for example, the outer edge of the substrate 115 includes a portion 500, and the boundary 300 is arranged between the portion 500 of the substrate 115 and the center 410 of the display region 402 in the direction crossing the direction in which the boundary 300 extends. At this time, the length 502 between the boundary 300 and the center 410 of the display region 402 may be equal to or more than a length 503 between the boundary 300 and the portion 500 of the substrate 115.

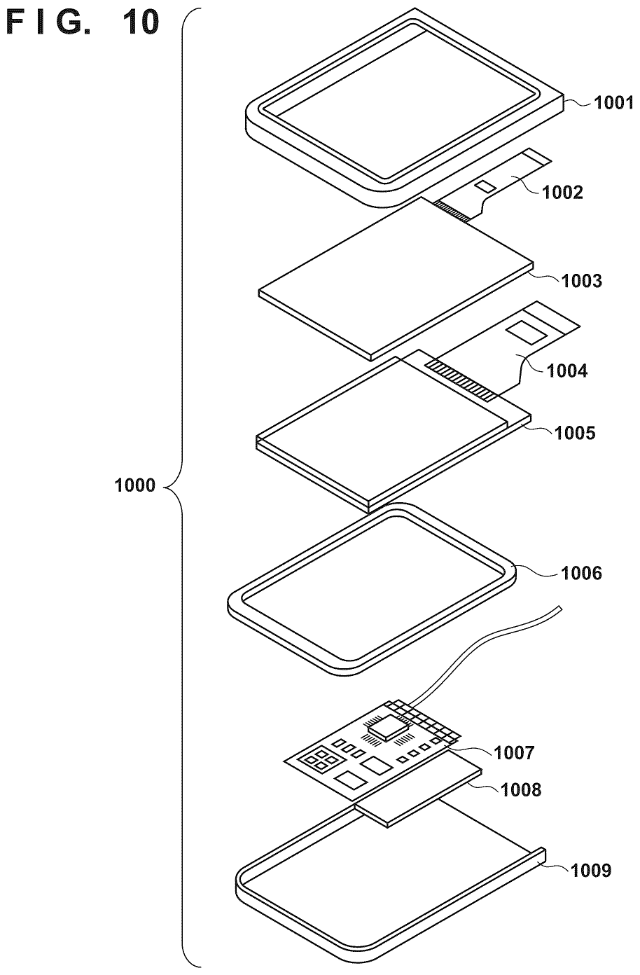

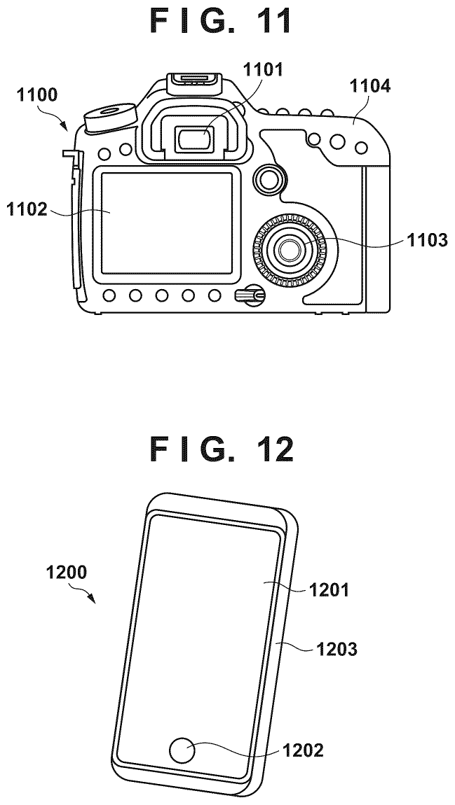

Also, assume that the boundary 300 is arranged between the side 412a and the center 410 of the display region 402, as shown in FIG. 5, and the visual field angle of the display region 402 in the light emitting device 100 is A degree. The visual field angle of the display region 402 is the design value of the visual field when the user views the display region 402 through an eyepiece optical system (for example, an optical system arranged in a viewfinder 1101 shown in FIG. 11) arranged in the light emitting device 100. In this case, the boundary 300 of stitching exposure may be arranged within the range of {(A/2−30)/A}×100[%] from the side 412a with respect to a length 511 of the display region in the direction crossing the boundary 300. For example, the visual field angle can be set to 105° to 120°. This is because the visual field to be clearly recognized by person's eyes in the horizontal direction is about ±30°. Hence, the boundary 300 may be arranged, for example, within the range of 30° or more in the direction crossing the boundary 300 from the center of the visual field angle through the eyepiece optical system. When the position of the boundary 300 of stitching exposure is deviated from the range of the visual field that a person readily recognizes, the difference of the light emission intensity caused by stitching exposure becomes more difficult to recognize by human vision.

The above description has been made using an example in which the boundary 300 is arranged between the center 410 of the display region 402 and the side 412a that is a short side among the sides 412 that form the outer edge of the display region 402. However, the present invention is not limited to this, and the same applies to a case where the boundary 300 is arranged between the center 410 of the display region 402 and the side 412b or 412d that is a long side among the sides 412 that form the outer edge of the display region 402. The short sides (sides 412a and 412c) and the long sides (sides 412b and 412d) may be replaced with each other below unless it is specifically explicitly stated.

There exists a technique called foveated rendering that lowers the resolution of the display region 402 generally in a peripheral visual field that a person is not gazing, thereby reducing a load in rendering processing. The present disclosure can obtain a higher effect by arranging the boundary 300 of stitching exposure in the region with the lower resolution when executing the foveated rendering.

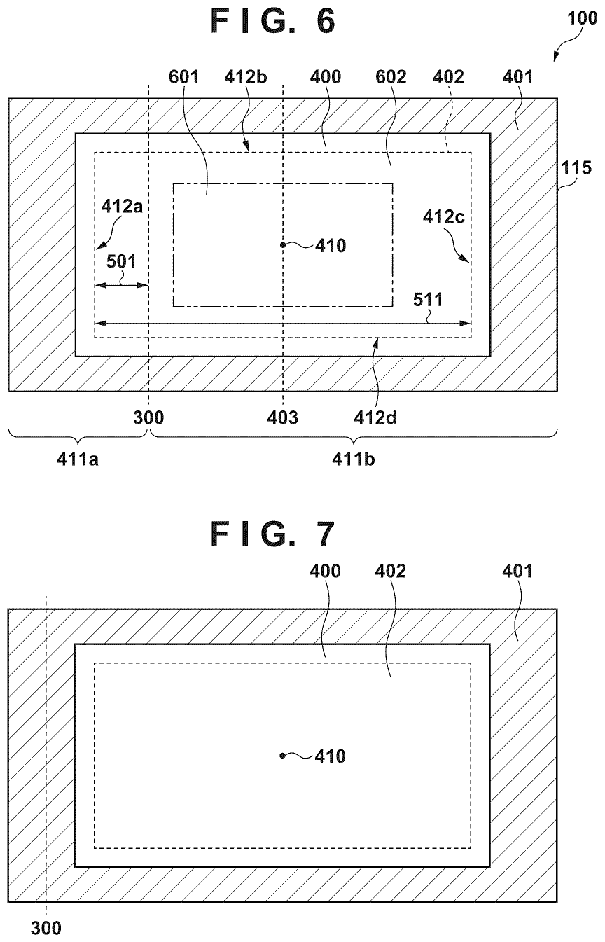

FIG. 6 is a view showing the display region 402 in a case where foveated rendering is performed. The display region 402 includes a display region 601, and a display region 602 in which the resolution of a displayed image is lower than that in the display region 601. The display region 601 is arranged at the center portion of the display region 402. In this case, the boundary 300 of stitching exposure passes through the display region 602. The boundary 300 may not pass through the display region 601. This makes it difficult for human vision to recognize the difference of the light emission intensity caused by stitching exposure.

For example, assume that of the display region 402, a region at the center whose size is ½ in the short side direction and the long side direction is set as the display region 601. In this case, the boundary 300 is arranged within the range of a distance ¼ the length 511 from the side 412a. The effect of the present disclosure can thus be obtained. Here, the display region 601 may be, for example, a region in which the arrangement density of the pixels PIX is higher than in the display region 602. Also, for example, the display region 602 may be a region in which the resolution of an image to be displayed is made lower than that in the display region 601 by signal processing.

In addition, the conductive pattern 121 formed using stitching exposure can be arranged even in a peripheral region 401. Hence, as shown in FIG. 7, the boundary 300 of stitching exposure may be arranged in the peripheral region 401. That is, the boundary 300 may not pass through the display region 402. In this case, the difference of the light emission intensity in the display region 402 caused by arranging the boundary 300 in the display region 402 hardly occurs. As a result, it is possible to further suppress image quality degradation of a displayed image caused by the boundary 300 of stitching exposure.

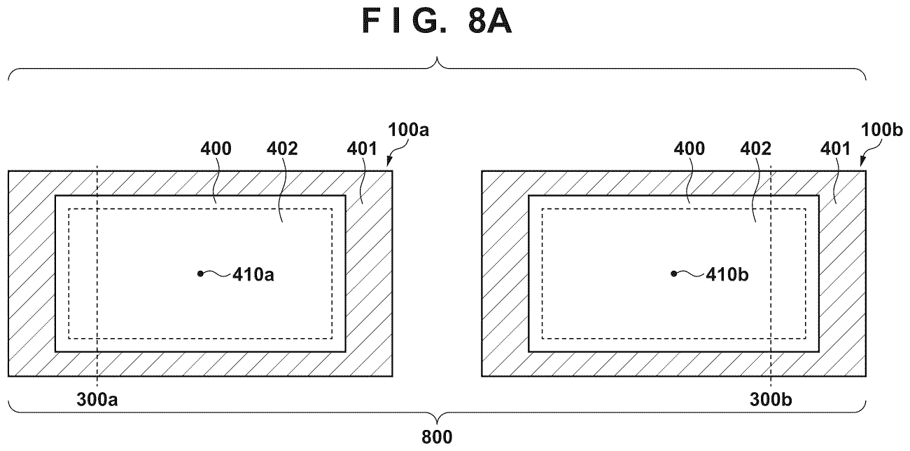

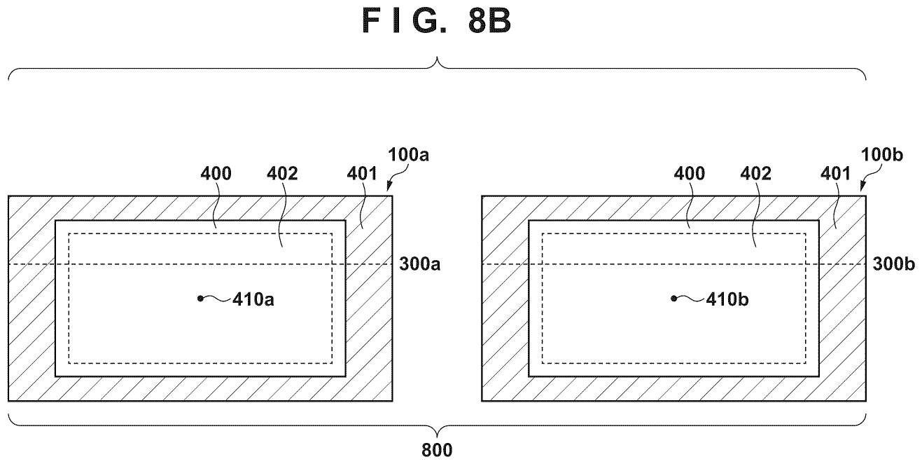

Next, an example in which the above-described light emitting device 100 is applied to a wearable device such as a head mounted display or smartglasses will be described. Each of FIGS. 8A and 8B shows a display device 800 included in a wearable device and configured to display an image. The display device 800 includes a plurality of light emitting devices including a light emitting device 100a arranged in correspondence with the left eye when a user wears it, and a light emitting device 100b arranged in correspondence with the right eye. In this case, as shown in FIG. 8A, the direction in which a boundary 300a of the light emitting device 100a is arranged with respect to a center 410a of the display region 402 of the light emitting device 100a when the user wears the wearable device and the direction in which a boundary 300b of the light emitting device 100b is arranged with respect to a center 410b of the display region 402 of the light emitting device 100b may be different from each other. More specifically, the boundary 300a of the light emitting device 100a may be arranged on the left side with respect to the center 410a of the display region 402 of the light emitting device 100a, and the boundary 300b of the light emitting device 100b may be arranged on the right side with respect to the center 410b of the display region 402 of the light emitting device 100b. Thus, in the light emitting devices 100a and 100b arranged in correspondence with the left and right eyes, respectively, the boundaries 300a and 300b of stitching exposure are arranged outside the visual field. It is therefore possible to suppress visually recognizing the difference of the light emission intensity caused by the boundary 300 of stitching exposure. As a result, in the wearable device including the display device 800 including the light emitting devices 100a and 100b, image quality degradation caused by stitching exposure in the light emitting devices 100a and 100b is suppressed.

Also, for example, as shown in FIG. 8B, when the user wears the wearable device, the boundaries 300a and 300b of the light emitting devices 100a and 100b may be arranged on the upper side with respect to the centers 410a and 410b of the display regions 402 of the light emitting devices 100a and 100b. The visual field to be clearly recognized by person's eyes in the vertical direction is about 15° on the upper side and about 20° on the lower side. Also, when relaxed, people are known to direct the line of sight downward. For this reason, the boundary 300 of stitching exposure is set on the upper side of the centers 410a and 410b of the display regions 402 in the light emitting devices 100. This makes it possible to suppress visually recognizing the difference of the light emission intensity caused by the boundary 300 of stitching exposure.

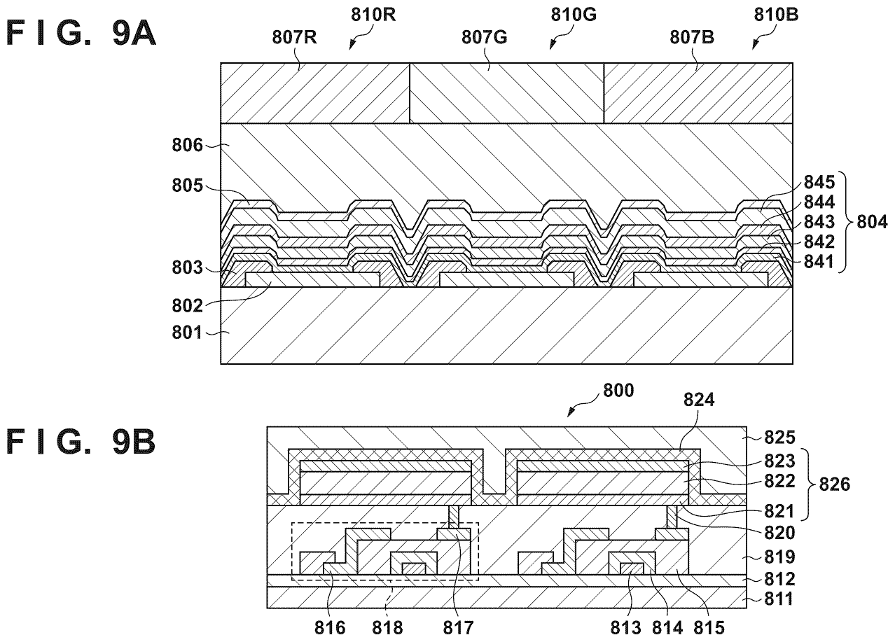

Here, application examples in which the light emitting device 100 according to this embodiment is applied to a display device, a photoelectric conversion device, an electronic apparatus, an illumination device, a moving body, and a wearable device will be described with reference to FIGS. 9A and 9B to 16A and 16B. The description will be given assuming that, for example, an organic light emitting element (OLED) such as an organic EL element using an organic light emitting material is arranged in the pixel PIX of the light emitting device 100. Details of each component arranged in the pixel PIX of the light emitting device 100 described above will be described first, and the application examples will be described after that.

The organic light emitting element according to an embodiment of the present disclosure includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, VN. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by dissolving the compound to be measured in a solvent such as toluene and irradiating it with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding −4.8 eV to the difference between the reduction potential of the obtained compound and that of ferrocene.

A conventionally known low molecular and high molecular hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

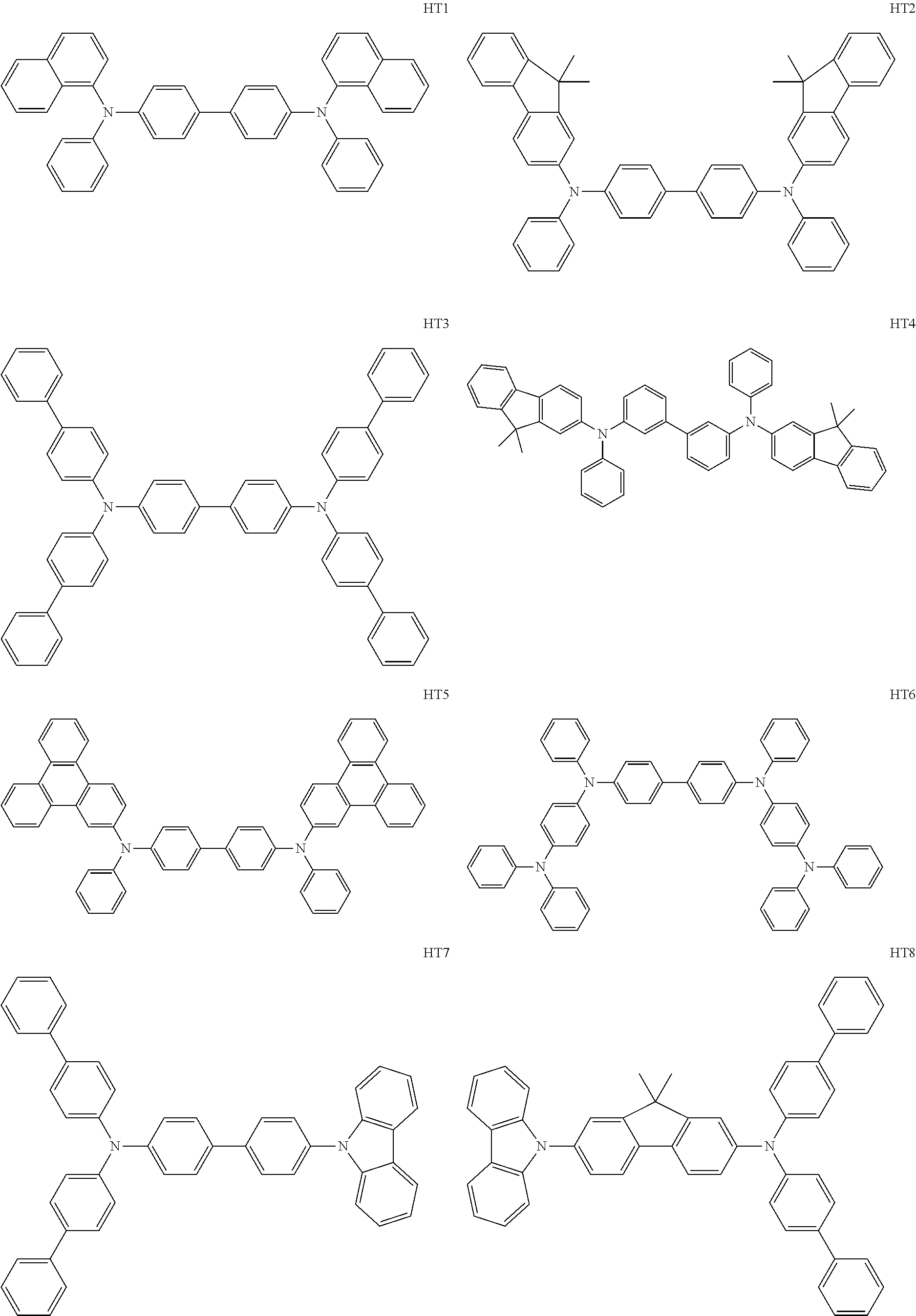

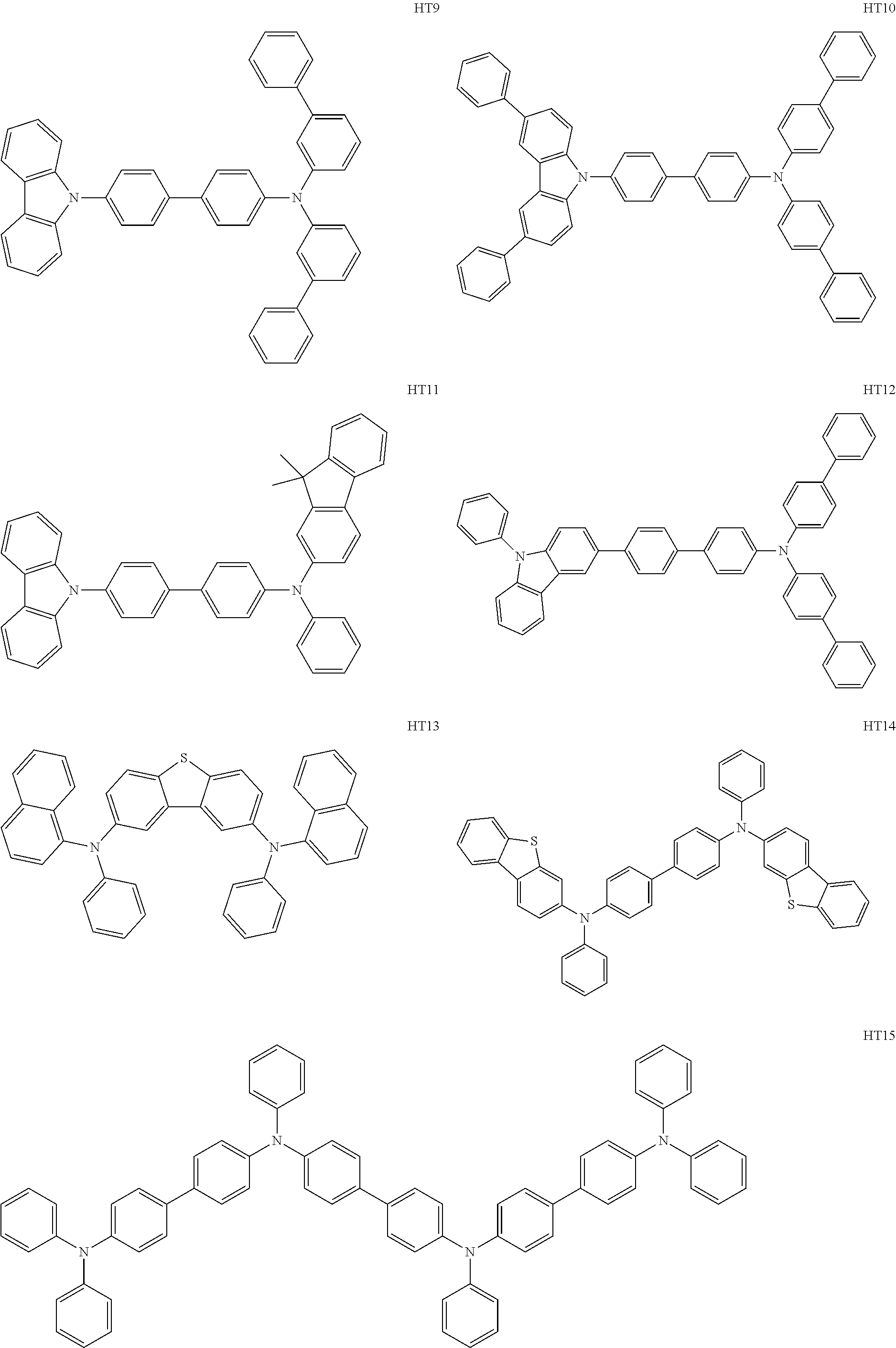

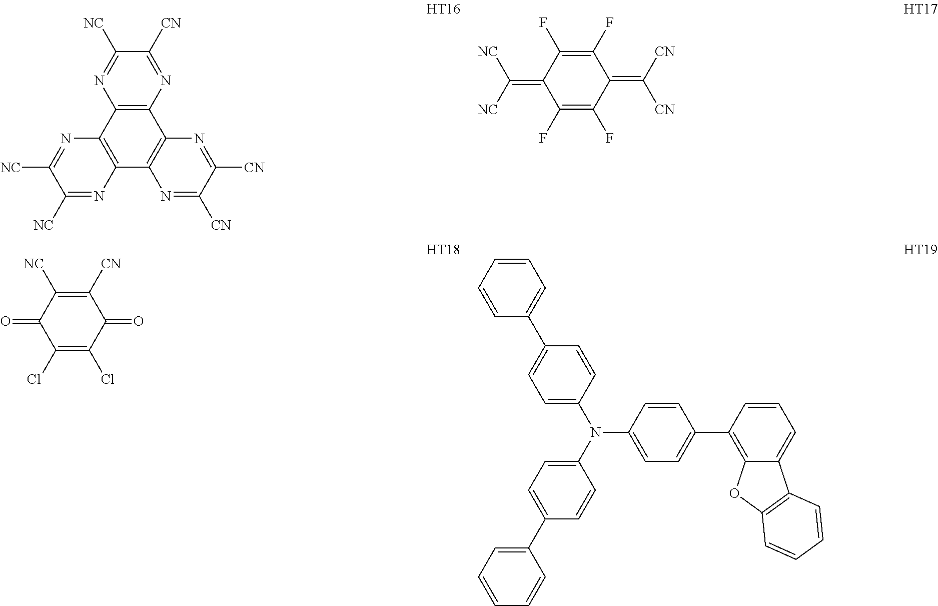

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

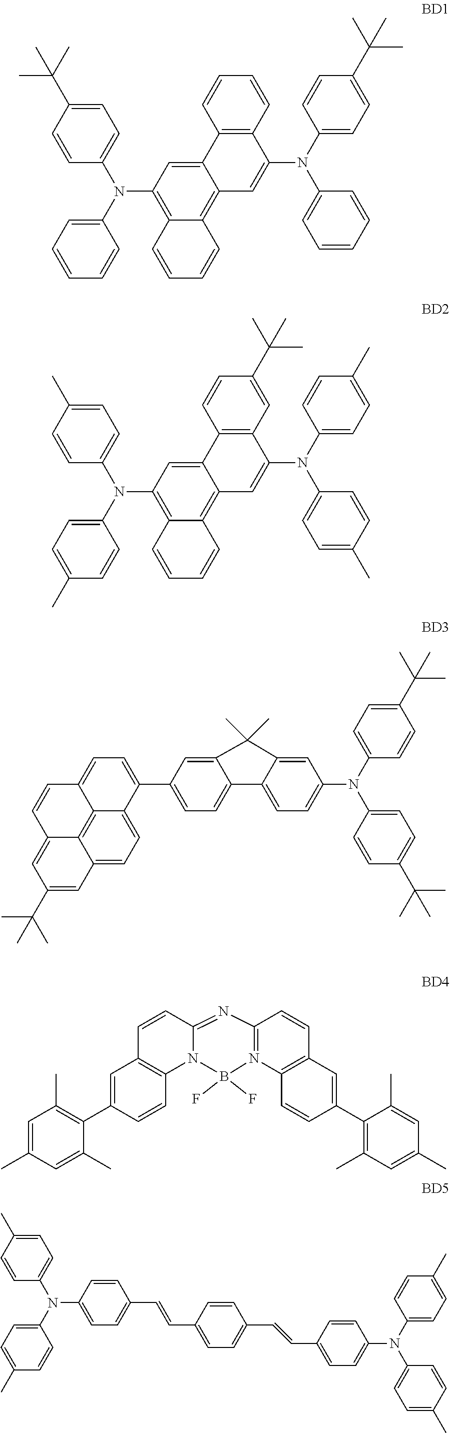

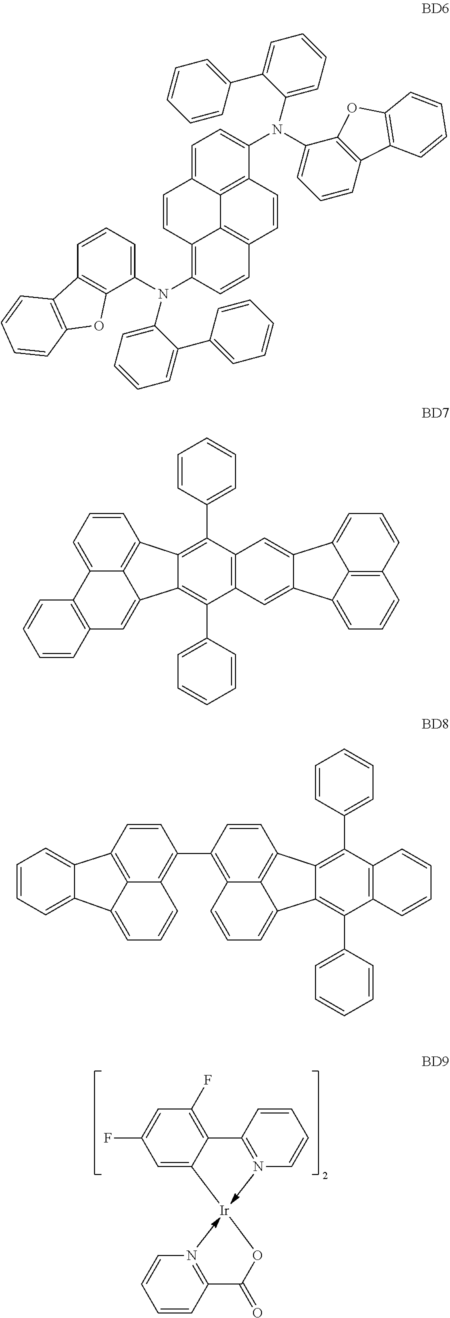

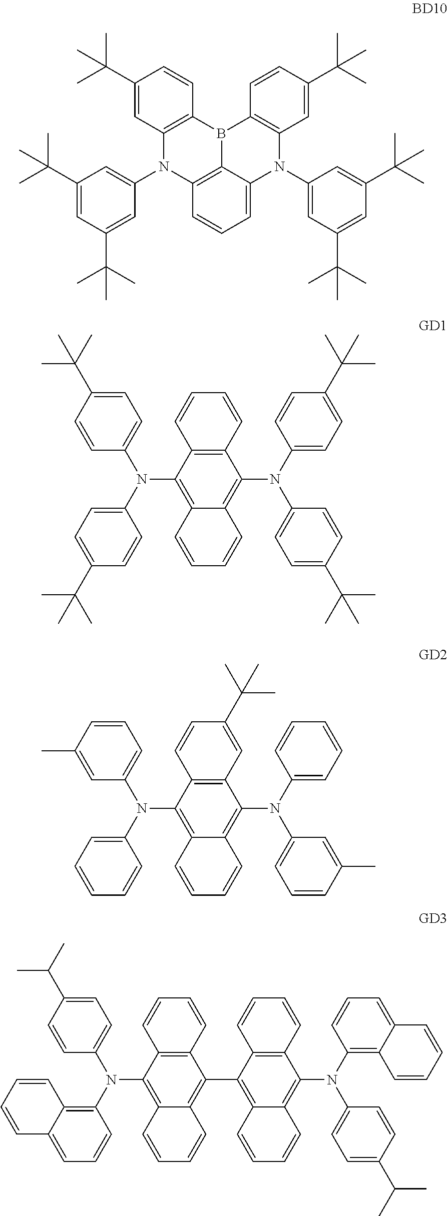

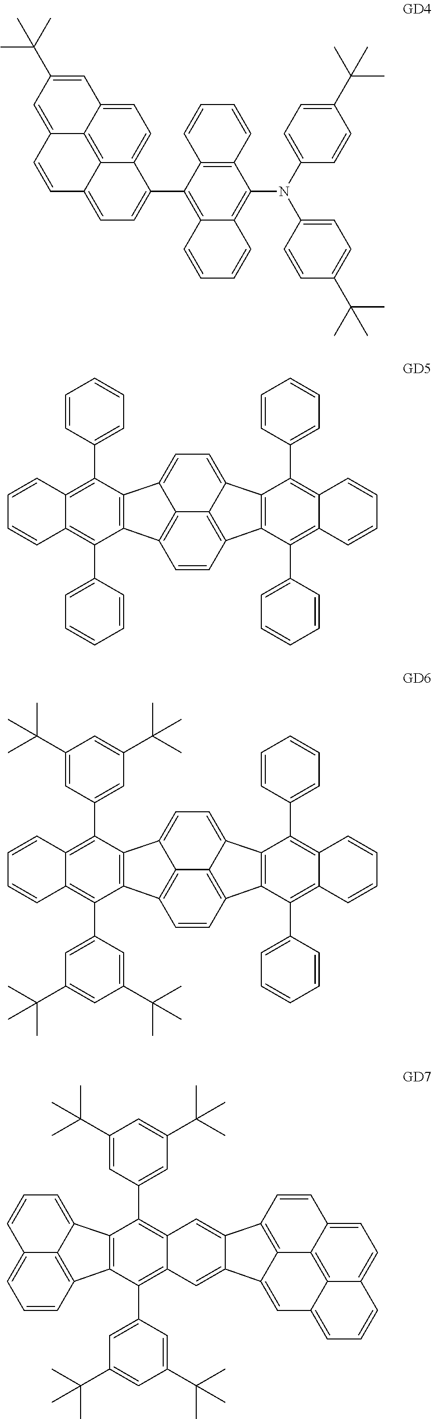

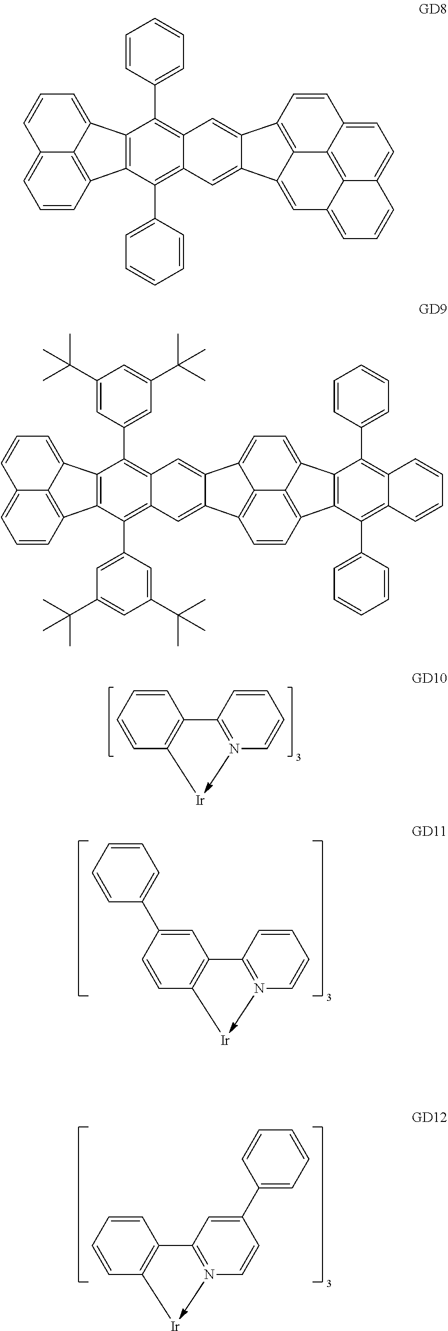

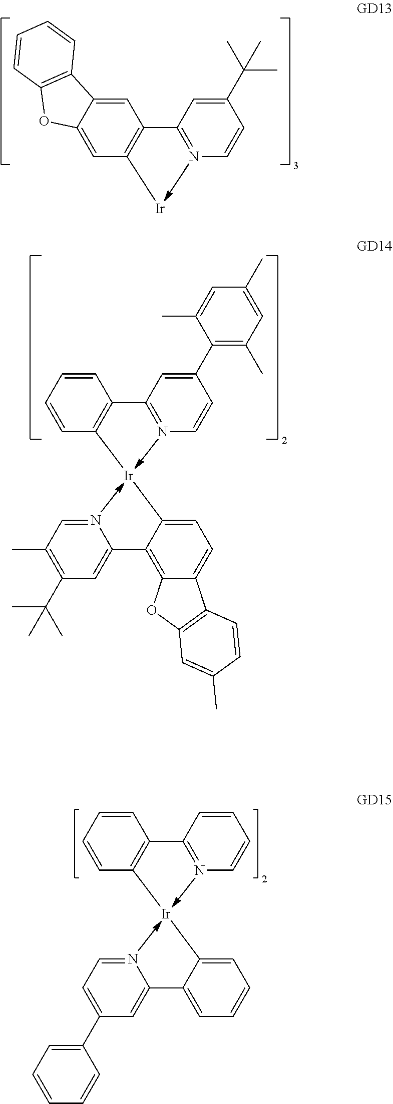

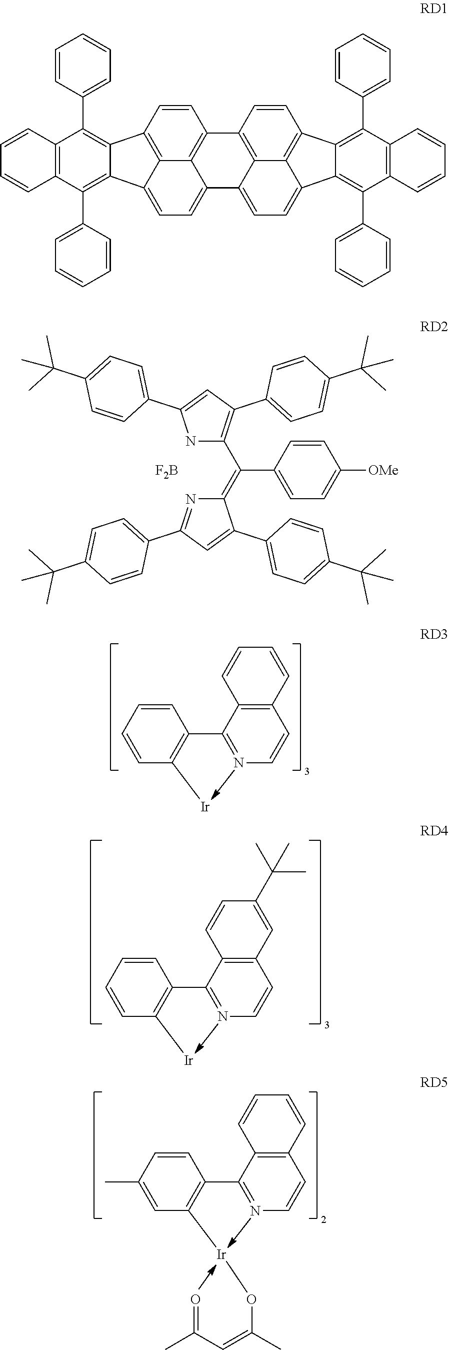

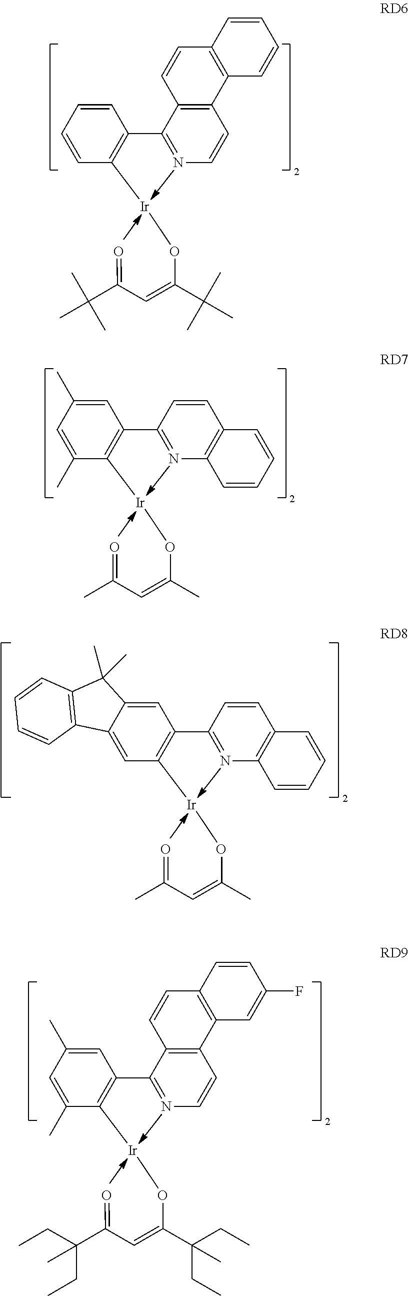

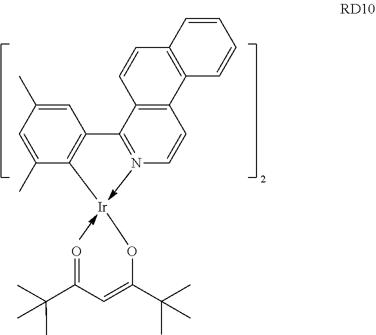

If the light emitting material is a hydrocarbon compound, this is suitable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is suitable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

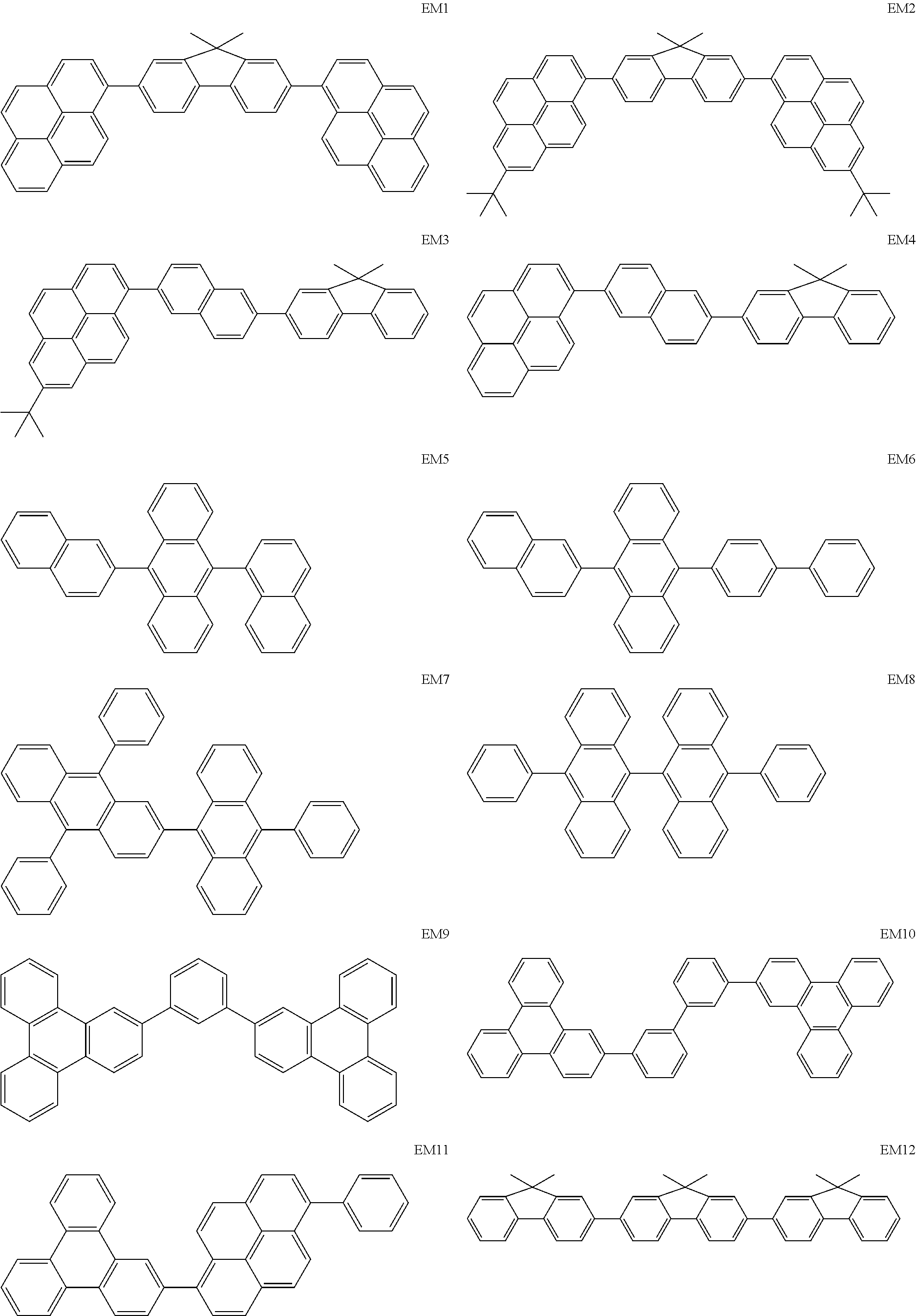

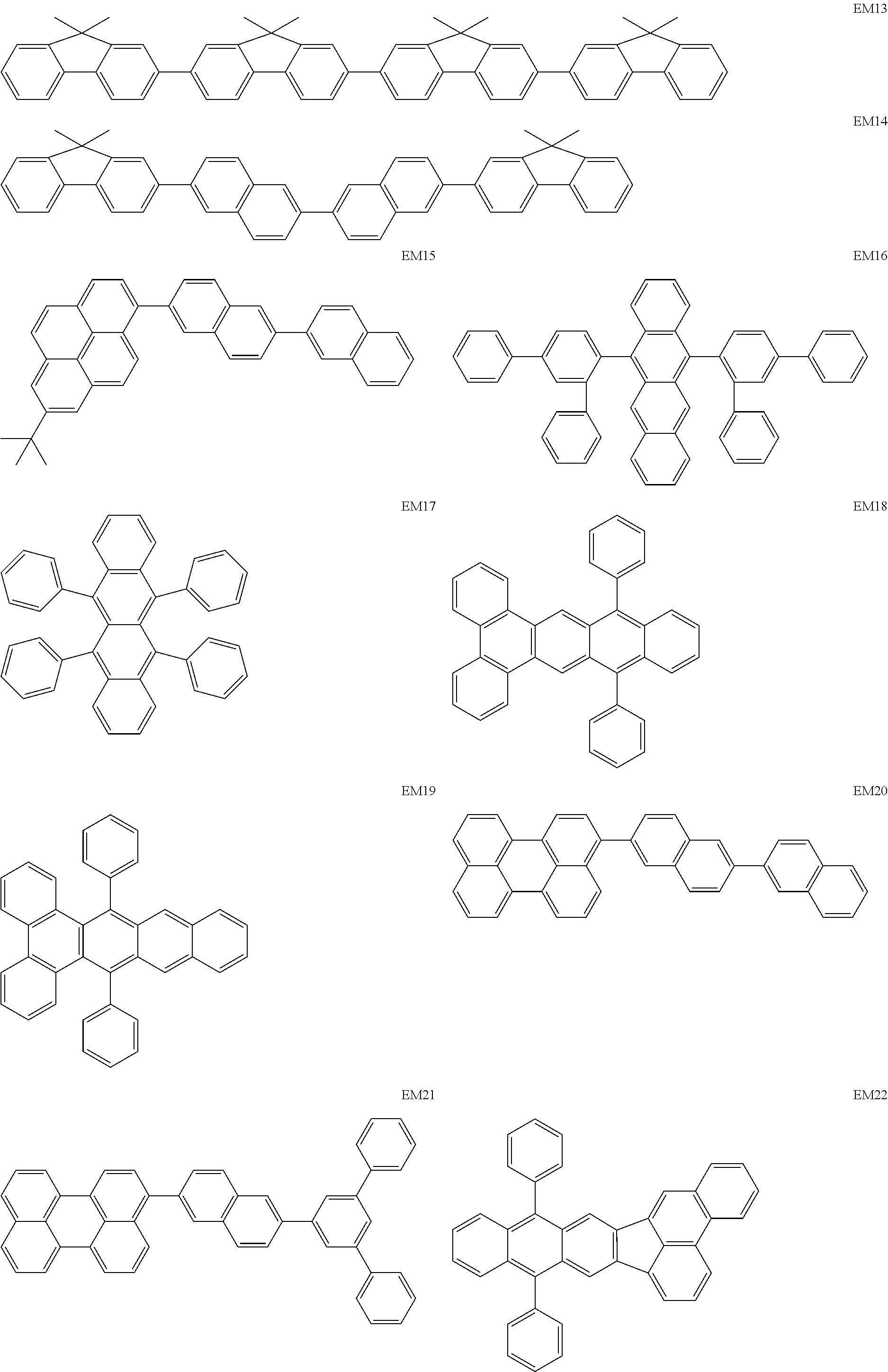

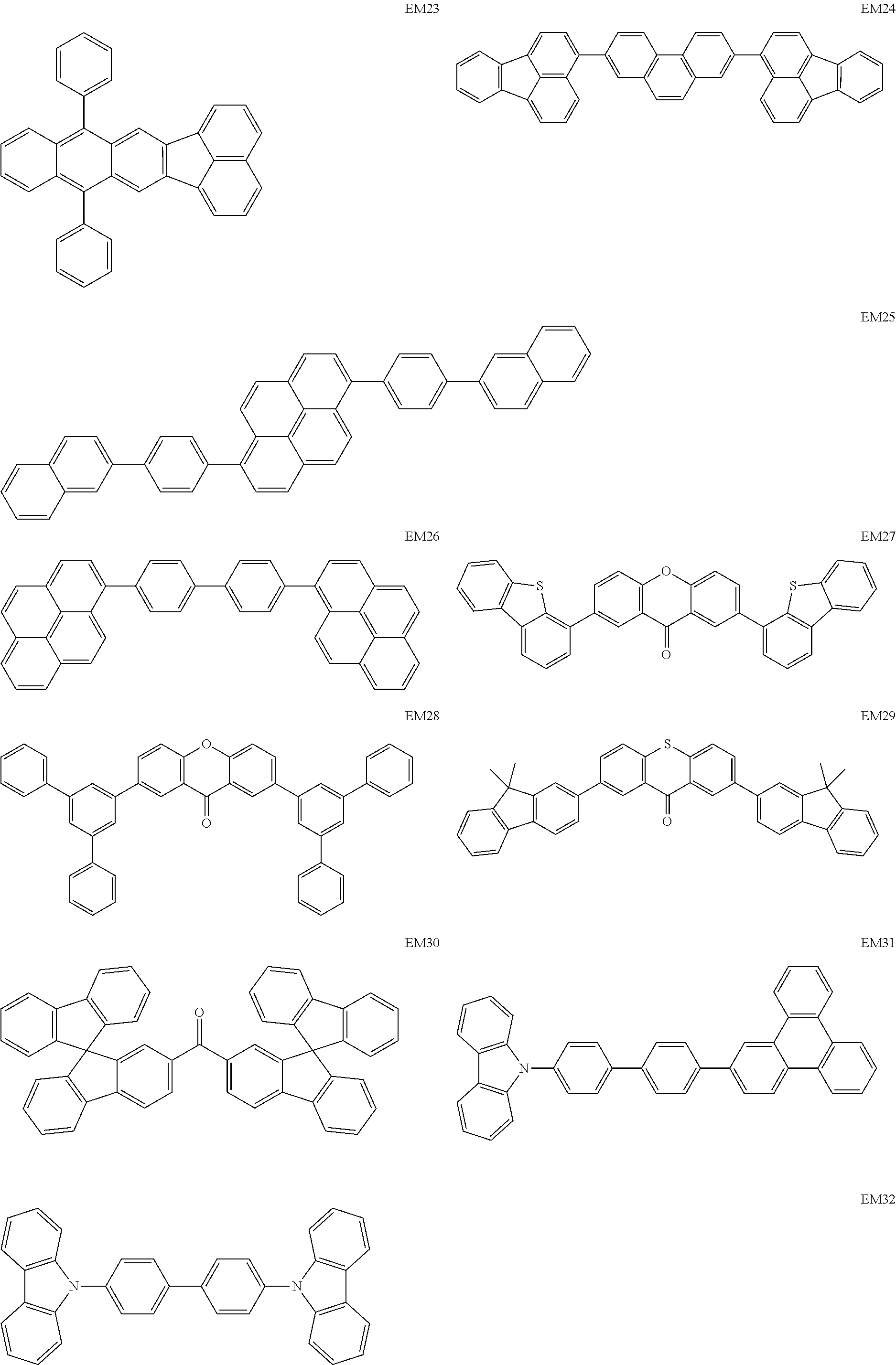

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material is suitably used for the hole blocking layer as well.

Detailed examples of compounds used as the electron transport material will be shown below. The material is not limited to these.

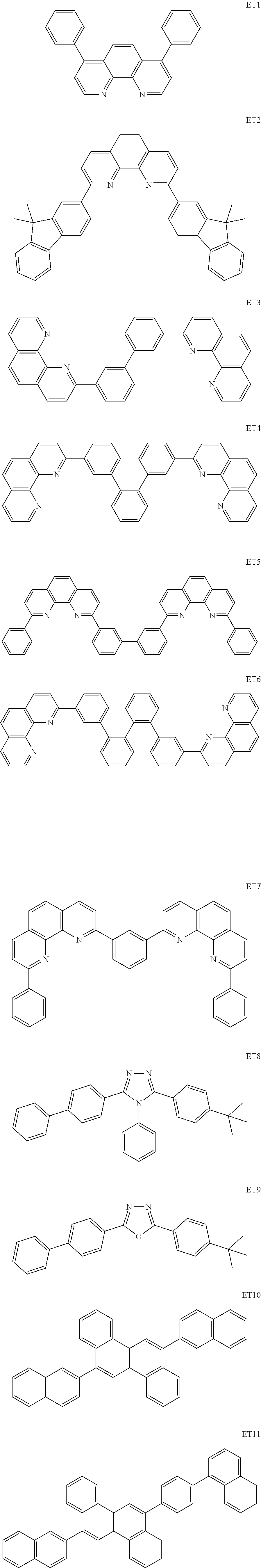

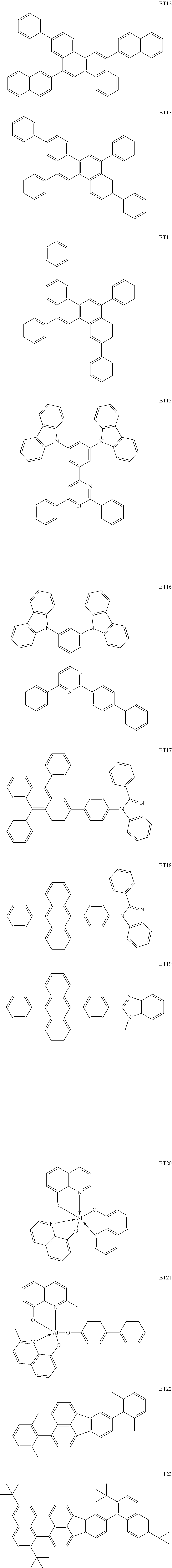

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (AI) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 600 (inclusive) to 900 (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes. If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generating portion is provided between the second light emitting layer and the third light emitting layer.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 9A shows an example of the pixel PIX arranged in the light emitting device 100. The pixel includes sub-pixels 810 (pixels PIX). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

The display device 800 (corresponding to the above-described light emitting device 100) shown in FIG. 9B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 9B. That is, one of the anode and cathode and one of the source electrode and drain electrode of the TFT are electrically connected. The TFT indicates a thin-film transistor.

In the display device 800 shown in FIG. 9B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 9B, but another switching element may be used instead.

The transistor used in the display device 800 shown in FIG. 9B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 9B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

FIG. 10 is a schematic view showing an example of the display device using the light emitting device 100 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 100 can be applied to the display panel 1005. The pixels PIX arranged in the light emitting device 100 functioning as the display panel 1005 are connected to a control circuit including the active elements such as transistors arranged on the circuit board 1007 and operate.

The display device 1000 shown in FIG. 10 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

FIG. 11 is a schematic view showing an example of the photoelectric conversion device using the light emitting device 100 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 according to this embodiment can be applied to the viewfinder 1101 or the rear display 1102 as a display unit. In this case, the light emitting device 100 can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device 100 in which the pixel PIX including the light emitting element using the organic light emitting material such as an organic EL element is arranged may be used for the viewfinder 1101 or the rear display 1102. This is so because the organic light emitting material has a high response speed. The light emitting device 100 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 100 may be applied to a display unit of an electronic apparatus. At this time, the display unit can have both a display function and an operation function. Examples of the portable terminal are a portable phone such as a smartphone, a tablet, and a head mounted display.

FIG. 12 is a schematic view showing an example of an electronic apparatus using the light emitting device 100 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 according to this embodiment can be applied to the display unit 1201.

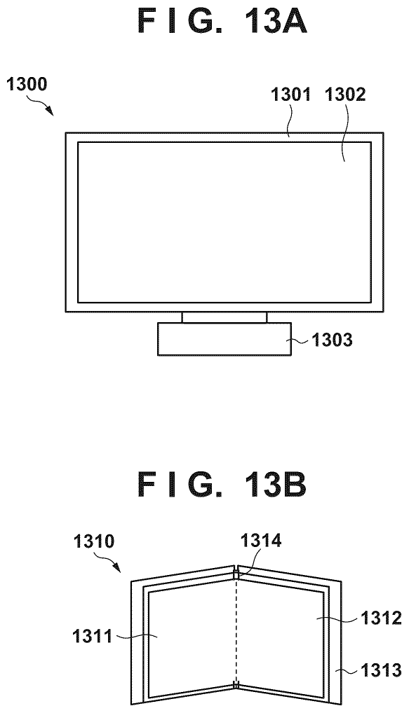

FIGS. 13A and 13B are schematic views showing examples of the display device using the light emitting device 100 according to this embodiment. FIG. 13A shows a display device such as a television monitor or a PC monitor. A display device 1300 includes a frame 1301 and a display unit 1302. The light emitting device 100 according to this embodiment can be applied to the display unit 1302. The display device 1300 can include a base 1303 that supports the frame 1301 and the display unit 1302. The base 1303 is not limited to the form shown in FIG. 13A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 13B is a schematic view showing another example of the display device using the light emitting device 100 according to this embodiment. A display device 1310 shown in FIG. 13B can be folded, and is a so-called foldable display device. The display device 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

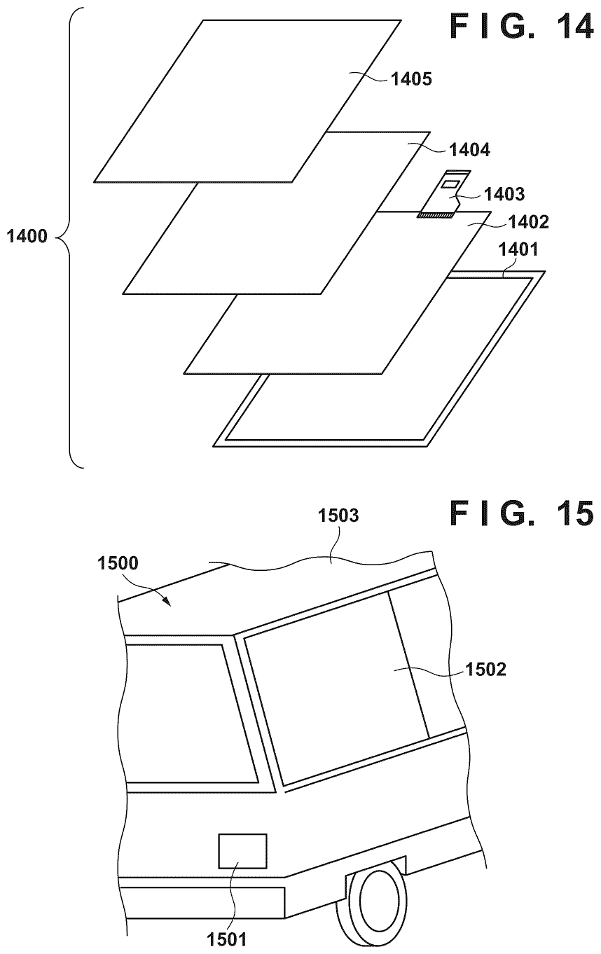

FIG. 14 is a schematic view showing an example of the illumination device using the light emitting device 100 according to this embodiment. An illumination device 1400 can include a housing 1401, a light source 1402, a circuit board 1403, an optical film 1404, and a light diffusing unit 1405. The light emitting device 100 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 100 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 15 is a schematic view of an automobile having a taillight as an example of a vehicle lighting appliance using the light emitting device 100 according to this embodiment. An automobile 1500 has a taillight 1501, and can have a form in which the taillight 1501 is turned on when performing a braking operation or the like. The light emitting device 100 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is somewhat high, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

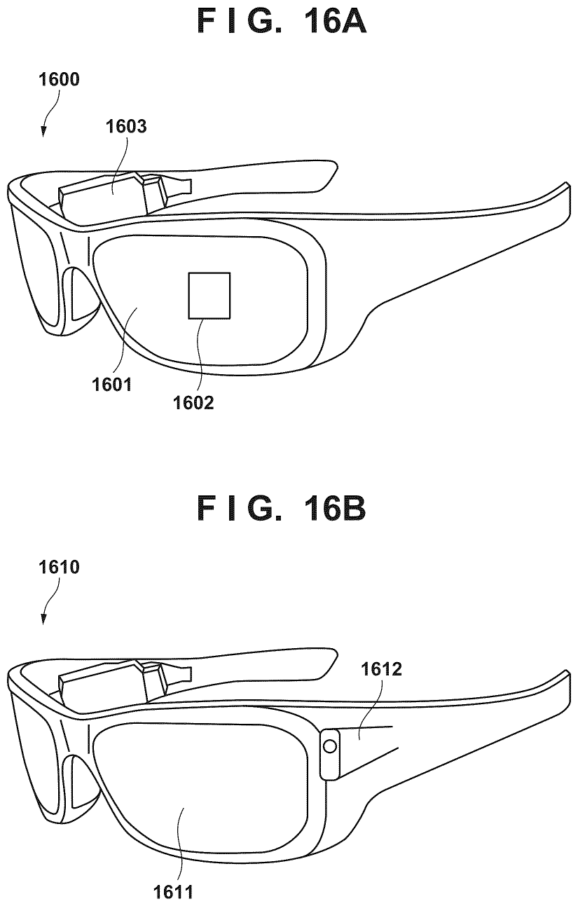

Further application examples of the light emitting device 100 according to this embodiment will be described with reference to FIGS. 16A and 16B. The light emitting device 100 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 16A. An image capturing device 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control device 1603. The control device 1603 functions as a power supply that supplies electric power to the image capturing device 1602 and the light emitting device 100 according to each embodiment. In addition, the control device 1603 controls the operations of the image capturing device 1602 and the light emitting device 100. An optical system configured to condense light to the image capturing device 1602 is formed on the lens 1601.

Glasses 1610 (smartglasses) according to one application example will be described with reference to FIG. 16B. The glasses 1610 include a control device 1612, and an image capturing device corresponding to the image capturing device 1602 and the light emitting device 100 are mounted on the control device 1612. The image capturing device in the control device 1612 and an optical system configured to project light emitted from the light emitting device 100 are formed in a lens 1611, and an image is projected to the lens 1611. The control device 1612 functions as a power supply that supplies electric power to the image capturing device and the light emitting device 100, and controls the operations of the image capturing device and the light emitting device 100. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to the embodiment of the present disclosure can include an image capturing device including a light receiving element, and control a displayed image based on the line-of-sight information of the user from the image capturing device.

More specifically, the light emitting device 100 decides a first visual field region at which the user is gazing and a second visual field region other than the first visual field region based on the line-of-sight information. The first visual field region and the second visual field region may be decided by the control device of the light emitting device 100, or those decided by an external control device may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100, the image capturing device, or an external device. If the external device holds the AI program, it is transmitted to the light emitting device 100 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-025574, filed Feb. 22, 2024, which is hereby incorporated by reference herein in its entirety.

What is claimed is:

1. Alight emitting device comprising, on a main surface of a semiconductor substrate, a display region in which a plurality of pixels are arranged, wherein
the main surface includes a first region in which a first conductive pattern is arranged, and a second region which is adjacent to the first region and in which a second conductive pattern is arranged,
each of the plurality of pixels includes an organic light emitting element, and a driving transistor configured to supply a current according to a luminance signal to the organic light emitting element,
each of the first conductive pattern and the second conductive pattern includes a conductive pattern connected to a gate electrode of the driving transistor in one of the plurality of pixels,
the first region and the second region are adjacent at a boundary with a deviation between the first conductive pattern and the second conductive pattern, and
the boundary does not pass through a center of the display region.

2. The device according to claim 1, wherein each of the first conductive pattern and the second conductive pattern includes a pattern arranged in a wiring layer closest to the gate electrode among a plurality of wiring layers arranged in the display region.

3. The device according to claim 1, wherein each of the first conductive pattern and the second conductive pattern includes a pattern arranged in a second closest wiring layer to the gate electrode among a plurality of wiring layers arranged in the display region.

4. The device according to claim 1, wherein each of the first conductive pattern and the second conductive pattern includes at least one of a plug connected to the gate electrode, a plug connected to a pattern arranged in a wiring layer closest to the gate electrode among a plurality of wiring layers arranged in the display region, and a plug connected to a pattern arranged in a second closest wiring layer to the gate electrode among the plurality of wiring layers.

5. The device according to claim 1, wherein each of the plurality of pixels further includes a write transistor configured to write the luminance signal to the gate electrode, and
each of the first conductive pattern and the second conductive pattern includes a conductive pattern connected to a gate electrode of the write transistor in one of the plurality of pixels.

6. The device according to claim 1, wherein the boundary passes through the display region.

7. The device according to claim 1, wherein the boundary does not pass through the display region.

8. The device according to claim 1, wherein in an orthogonal projection to the main surface,
an outer edge of the semiconductor substrate includes a first portion,
in a direction crossing a direction in which the boundary extends, the boundary is arranged between the first portion and the center, and
a length between the boundary and the center is not less than a length between the boundary and the first portion.

9. The device according to claim 1, wherein in an orthogonal projection to the main surface,
the display region has a rectangular shape,
in a direction crossing a direction in which the boundary extends, the boundary is arranged between the center and a first side among sides that form an outer edge of the display region, and
a length between the boundary and the center is not less than a length between the boundary and the first side.

10. The device according to claim 1, further comprising an eyepiece optical system,
wherein in an orthogonal projection to the main surface,
the display region has a rectangular shape,
in a direction crossing a direction in which the boundary extends, the boundary is arranged between the center and a first side among sides that form an outer edge of the display region, and
if a visual field angle through the eyepiece optical system is defined as A degree, the boundary is arranged within a range of {(A/2−30)/A}×100[%] from the first side with respect to a length of the display region in the crossing direction.

11. The device according to claim 1, further comprising an eyepiece optical system,
wherein in an orthogonal projection to the main surface,
the display region has a rectangular shape,
in a direction crossing a direction in which the boundary extends, the boundary is arranged between the center and a first side among sides that form an outer edge of the display region, and
the boundary is arranged within a range of not less than 30° in the crossing direction from a center of a visual field angle through the eyepiece optical system.

12. The device according to claim 9, wherein the rectangular shape has a long side and a short side, and
the first side forms the long side.

13. The device according to claim 9, wherein the rectangular shape has a long side and a short side, and
the first side forms the short side.

14. The device according to claim 9, wherein the boundary extends parallel to a direction in which the first side extends.

15. The device according to claim 1, wherein the display region includes a first display region, and a second display region in which a resolution of a displayed image is lower than that of the first display region, and
the boundary passes through the second display region.

16. The device according to claim 15, wherein the boundary does not pass through the first display region.

17. The device according to claim 15, wherein an arrangement density of the pixels in the first display region is higher than that in the second display region.

18. A wearable device including a display device configured to display an image,
wherein the display device includes the light emitting device according to claim 1.

19. The device according to claim 18, wherein the display device includes a plurality of light emitting devices including a first light emitting device arranged in correspondence with a left eye, and a second light emitting device arranged in correspondence with a right eye when a user wears the wearable device.

20. The device according to claim 19, wherein when the user wears the wearable device, a direction in which the boundary of the first light emitting device is arranged with respect to the center of the display region of the first light emitting device and a direction in which the boundary of the second light emitting device is arranged with respect to the center of the display region of the second light emitting device are different from each other.

21. The device according to claim 19, wherein when the user wears the wearable device, the boundary of the first light emitting device is arranged on a left side with respect to the center of the display region of the first light emitting device, and the boundary of the second light emitting device is arranged on a right side with respect to the center of the display region of the second light emitting device.

22. The device according to claim 19, wherein when the user wears the wearable device, the boundary of each of the first light emitting device and the second light emitting device is arranged on an upper side with respect to the center of the display region of each of the first light emitting device and the second light emitting device.

23. A display device comprising the light emitting device according to claim 1, and a control circuit connected to the light emitting device.

24. A photoelectric conversion device comprising an optical unit including a plurality of lenses, an image sensor configured to receive light having passed through the optical unit, and a display configured to display an image,
wherein the display includes the light emitting device according to claim 1.

25. An electronic apparatus comprising a housing provided with a display, and a communication unit provided in the housing and configured to perform external communication,
wherein the display includes the light emitting device according to claim 1.

26. An illumination device comprising a light source, and at least one of a light diffusing unit and an optical film,
wherein the light source includes the light emitting device according to claim 1.

27. A moving body comprising a main body, and a lighting appliance provided in the main body,
wherein the lighting appliance includes the light emitting device according to claim 1.
